(19) United States
(12) Patent Application Publication
(10) Pub. No.: US 2026/0110968 A1
(43) Pub. Date: Apr. 23, 2026

(54) FILM STACK FOR EXTREME ULTRAVIOLET (EUV) LITHOGRAPHY WITH REFLOWABLE UNDERLAYER

(71) Applicant: Applied Materials, Inc., Santa Clara, CA (US)

(72) Inventors: RUDY WOJTECKI, East Garrison, CA (US); NASRIN KAZEM, Santa Clara, CA (US)

(21) Appl. No.: 19/342,156

(22) Filed: Sep. 26, 2025

Related U.S. Application Data
(60) Provisional application No. 63/708,676, filed on Oct. 17, 2024.

(51) Int. Cl. G03F 7/09; G03F 7/00; G03F 7/004; G03F 7/36

(52) U.S. Cl. CPC G03F 7/094; G03F 7/0043; G03F 7/36; G03F 7/70033

(57) ABSTRACT

Embodiments described herein relate to a method of developing a resist layer on a substrate that has been selectively exposed with a lithography process, where an underlayer is below the resist layer. In an embodiment, the method includes developing the resist layer with a dry develop process to form an opening in the resist layer, where a temperature of the dry develop process using the Kelvin scale is within ±15% of a glass transition temperature of the underlayer.

### CROSS-REFERENCE TO RELATED APPLICATIONS

This application claims the benefit of U.S. Provisional Application No. 63/708,676, filed on Oct. 17, 2024, the entire contents of which are hereby incorporated by reference herein.

### BACKGROUND

### 1) Field

Embodiments relate to the field of semiconductor manufacturing and, in particular, dry development processes for extreme ultra violet (EUV) photoresist layers with a reflowable underlayer.

### 2) Description of Related Art

Extreme ultraviolet (EUV) photoresists allow for the continued scaling to smaller features that are patterned on a semiconductor substrate. In an EUV lithography process, EUV radiation is selectively applied to regions of the photoresist layer in order to generate a solubility switch that enables the formation of a latent image within the photoresist layer. The latent image corresponds to the portions of the photoresist layer that have undergone the solubility switch as a result of a chemical reaction that is induced by the EUV exposure. After the latent image is produced within the photoresist layer, a developing process may be used in order to generate a pattern in the photoresist layer.

Typically, EUV compatible resists suffer from poor sensitivity. That is, a large dose is needed in order to provide the necessary solubility switch in order to provide adequate pattern formation (e.g., with suitable line edge roughness (LER), line width roughness (LWR), critical dimension (CD) uniformity, and/or the like). The larger dose increases the exposure time, which may be a bottleneck in the EUV lithography process.

One solution to reduce the necessary dose is to incorporate an underlayer below the resist layer. The underlayer may also react to the EUV exposure in order to diffuse species into the overlying resist layer. The additional species diffused into the resist layer may participate in the chemical reactions in order to allow for lower overall EUV doses. However, the underlayer may also generate issues during the patterning process. For example, the reactions within the resist layer during exposure and/or developing may result in a volumetric change in the resist layer. This can lead to residual stress within the resist layer since there is no way to dissipate the stress into the underlayer. As such, the residual stress is dissipated through the increase of line roughness (e.g., LER and/or LWR), line wiggling, and/or the like.

### SUMMARY

Embodiments described herein relate to a method of developing a resist layer on a substrate that has been selectively exposed with a lithography process, where an underlayer is below the resist layer. In an embodiment, the method includes developing the resist layer with a dry develop process to form an opening in the resist layer, where a temperature of the dry develop process using the Kelvin scale is within ±15% of a glass transition temperature of the underlayer.

Embodiments described herein relate to a method of developing a resist layer on a substrate that has been selectively exposed with a lithography process, where an underlayer is below the resist layer. In an embodiment, the method includes developing the resist layer with a dry develop process to form an opening in the resist layer, where the underlayer is deformable to dissipate stress that is generated in the resist layer during the dry develop process.

Embodiments described herein relate to a method that includes developing a resist layer that is provided over an underlayer with a dry develop process to form an opening through the resist layer, where a temperature of the dry develop process using the Kelvin scale is within ±15% of a glass transition temperature of the underlayer.

### BRIEF DESCRIPTION OF THE DRAWINGS

FIG. 1A-1E are illustrations that depict a process for developing a resist layer that results in residual stress being formed in the resist layer that leads to high LER and/or LWR, in accordance with an embodiment.

FIG. 2A is a cross-sectional illustration of a developed resist layer over an underlayer that is capable of dissipating the residual stress in the resist layer in order to improved LER and/or LWR, in accordance with an embodiment.

FIG. 2B is a graph of the elastic modulus versus temperature of a material used for the underlayer, in accordance with an embodiment.

FIG. 3A-3F are illustrations depicting a process for developing a resist layer over a reflowable underlayer with a dry develop process, in accordance with an embodiment.

FIG. 4 is a flow diagram of a process for developing a resist layer over a reflowable underlayer with a dry develop process, in accordance with an embodiment.

FIG. 5 illustrates a block diagram of an exemplary computer system that may be used in conjunction with a processing tool, in accordance with an embodiment.

### DETAILED DESCRIPTION

Embodiments described herein include dry development processes for extreme ultra violet (EUV) photoresist layers with a reflowable underlayer. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately.

However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, underlayers are sometimes used below the resist layer in order to reduce the necessary dose of extreme ultraviolet (EUV) and/or deep ultraviolet (DUV) radiation that is required to provide a desired solubility switch within the resist layer. After exposure, the resist layer is developed. Often a wet develop process is used. However, wet develop chemistries may result in the generation of capillary forces that can lead to mechanical deformations (e.g., pattern collapse, poor LER, and/or LWR characteristics). Accordingly, dry develop chemistries are being investigate in order to avoid the capillary forces.

One such dry develop chemistry is an organic acid chemistry, such as an acetic acid. However, such development may still result in LER and/or LWR characteristics that are undesirable. This can be due, at least in part, to the generation of residual stress within the resist layer during the exposure process and/or the development process. For example, ligand loss and film shrinking can produce a volumetric change in the resist layer. Since a surface of the resist layer that is in contact with the underlayer is constrained, the stress is not able to dissipate out of the resist layer. This results in the sidewalls of the resist layer being warped in an attempt to mitigate some of the stress. This leads to surfaces with high LER and/or LWR values.

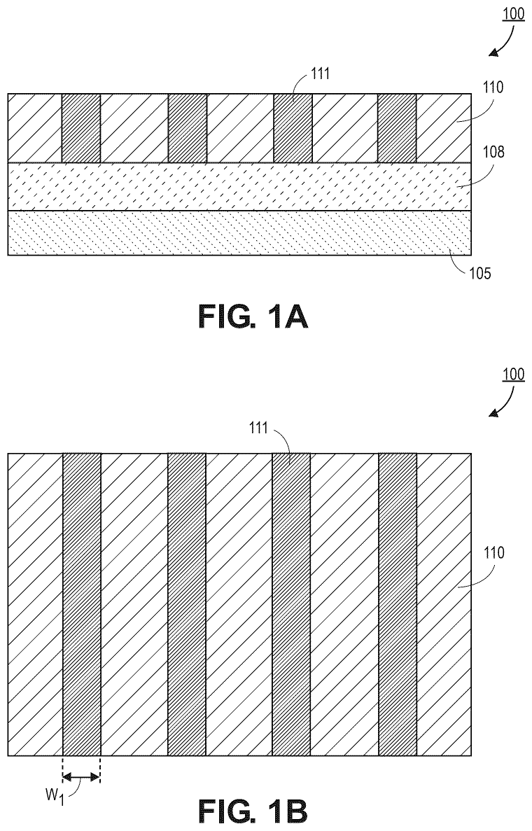

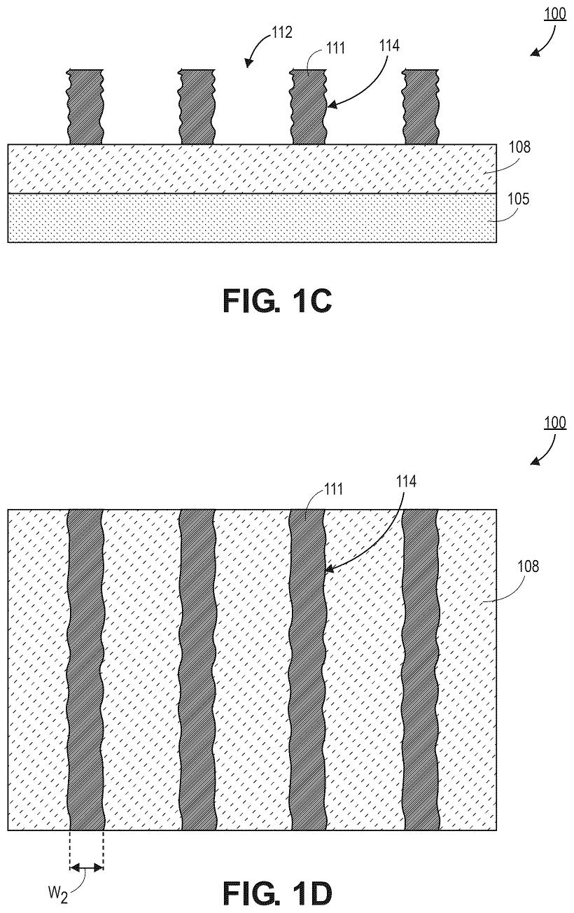

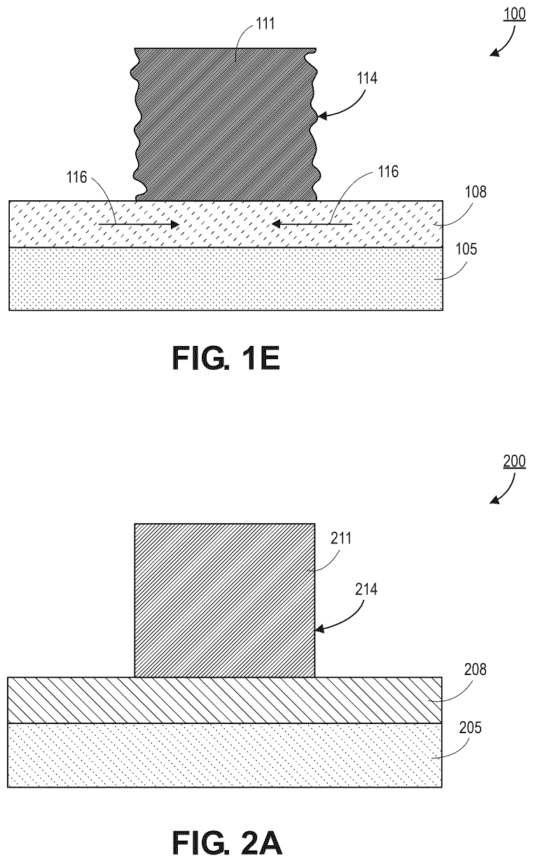

An example of such an embodiment is shown in FIG. 1A-1E. Referring now to FIG. 1A, a cross-sectional illustration of a portion of a device 100 is shown, in accordance with an embodiment. In an embodiment, the device 100 may include a substrate 105, an underlayer 108, and a resist layer 110. The substrate 105 may be a semiconductor substrate or the like. The resist layer 110 may be a metal oxide resist, and the underlayer 108 may include a carbon based polymer. As shown, the resist layer 110 has been exposed (e.g., with EUV and/or DUV radiation) to form a latent image (as indicated by the different shading). The latent image may include a plurality of lines 111. As shown in the corresponding plan view illustration of FIG. 1B, the lines 111 may have a first width W₁.

Referring now to FIG. 1C, a cross-sectional illustration of the portion of the device 100 after the resist layer 110 is developed to form openings 112 is shown, in accordance with an embodiment. As shown, the lines 111 may persist, and the remainder of the resist layer 110 is removed. The develop process for the resist layer 110 may comprise a dry develop process in some embodiments. As shown in the corresponding plan view illustration in FIG. 1D, the lines 111 may have a volumetric change. For example, the lines may have a reduction in width so that the lines now have a second width W₂ that is smaller than the first width W₁.

As can be appreciated, the volumetric change may induce residual stress within the lines 111. Since the lines 111 are secured to the underlayer 108, the lines 111 are not able to freely move in order to dissipate the residual stress down into the underlayer 108. Accordingly, the residual stress is exhibited as an increase in the surface roughness of the sidewall surfaces 114 of the lines 111. That is, the lines 111 may have undesirable levels of LER and/or LWR.

Referring now to FIG. 1E, a zoomed in illustration of the device 100 after the dry develop of the resist layer 110 is shown, in accordance with an embodiment. As shown, the volumetric change within the line 111 is not able to be dissipated through the underlayer 108. As such, an opposing stress 116 is induced into the underlayer 108. When the underlayer 108 is not able to deform, the stress within the line 111 and the underlayer persists and results in poor LER and/or LWR of the sidewall surfaces 114.

Accordingly, embodiments disclosed herein include underlayer materials that are reflowable. In a particular embodiment, the underlayer material is brought to a temperature that is approximately equal to the glass transition temperature of the underlayer material during the develop process. The glass transition temperature provides sufficient structural support to retain good pattern formation in the resist layer, while also allowing for deformation of the underlayer in order to accommodate the stress induced in the patterned lines of the resist layer. That is, embodiments disclosed herein may include a dry develop process that is implemented at an elevated temperature. For example, the dry develop chemistry may comprise an organic acid at a temperature between approximately 160° C. and approximately 210° C. or between approximately 460 Kelvin (K) and approximately 485 K.

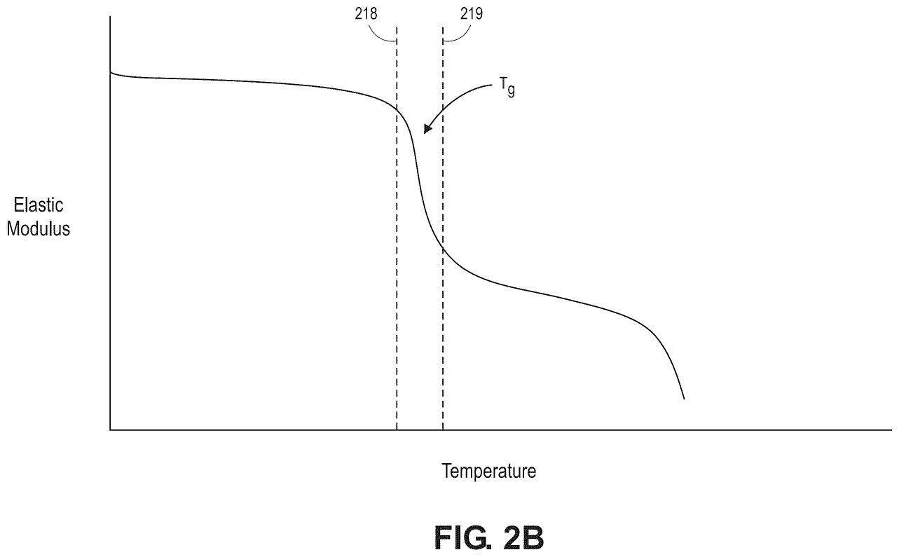

Referring now to FIG. 2A, a cross-sectional illustration of a portion of a device 200 is shown, in accordance with an embodiment. In an embodiment, the device 200 may be similar to the device 100 described above. For example, the device 200 may comprise a substrate 205, an underlayer 208, and lines 211 (that are patterned from a resist layer that overlies the underlayer 208). However, the device 200 differs from the device 100 in that the underlayer 208 is a material that is reflowable. For example, the reflow characteristic of the underlayer 208 is shown in FIG. 2B.

As shown in FIG. 2B, the elastic modulus (Y-axis) decreases with increased temperature (X-axis). In a particular embodiment, the material for the underlayer 208 is chosen so that the glass transition temperature (between lines 218 and 219) is close to the processing temperature of the dry development process. For example, the lines 218 and 219 may be at approximately 160° C. (line 218) and approximately 210° C. (line 219) or, when expressed in the Kelvin scale, approximately 430 K (line 218) and approximately 485 K (line 219). More generally, the temperature used for the dry develop process of the resist layer (when referring to the Kelvin scale) may be within ±15% of the glass transition temperature of the material of the underlayer 208, within ±10% of the glass transition temperature of the material of the underlayer 208, or within ±5% of the glass transition temperature of the underlayer 208.

In some embodiments, the material for the underlayer 208 may be a material that is compatible with patterning stack deposition processes and are structurally similar to existing polymer underlayer materials. Though in some embodiments, the underlayer 208 may be deposited with a dry deposition process (e.g., chemical vapor deposition (CVD), atomic layer deposition (ALD), or the like). In some embodiments, the underlayer 208 may comprise a polymer, such as an epoxy resin, an amide, or an imide. In a particular embodiment, the underlayer 208 may comprise N, N-dimethylacrylamide (DMMA), methyl methacrylate (MMA), polydimethylglutarimide (PMGI), or t-butyl maleimide.

In a particular embodiment, the EUV resist material may comprise a metal oxide resist (MOR) material. The resist material may also include an organometallic oxide material. In an embodiment a MOR material may comprise a photoresist material with one or more metals (e.g., tin, indium, hafnium, zinc, zirconium, or any combination thereof). The MOR material may also comprise an organotin-oxo photoresist material, an organoindium-oxo photoresist material, or the like.

By bringing the underlayer 208 to a temperature around the glass transition temperature during the dry develop process, the underlayer 208 is able to deform in response to stress generated in the lines 211. The deformation of the underlayer 208 allows the stress to be dissipated into the underlayer 208. As such, the sidewall surfaces 214 of the line 211 do not have to accommodate the stress. Accordingly, the sidewall surfaces 214 have a reduced LER and/or LWR compared to structures that include an underlayer that is not reflowable (e.g., similar to the underlayer 108 described in greater detail above).

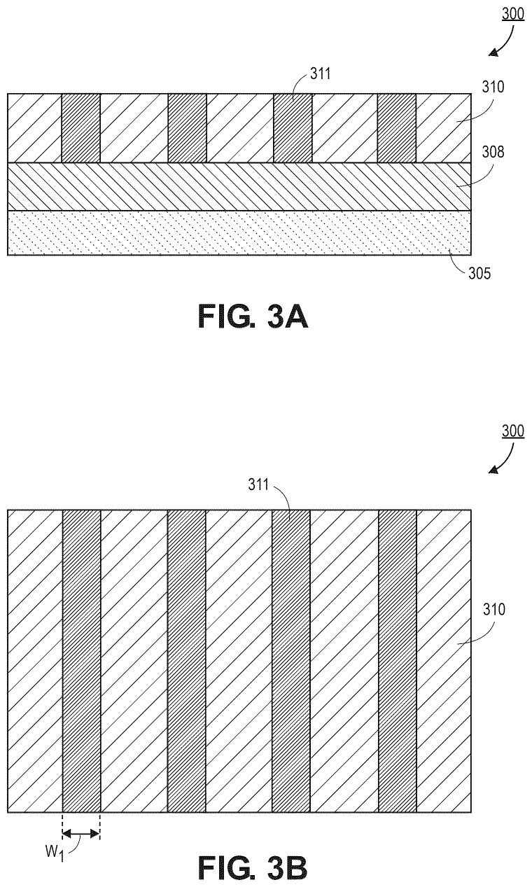

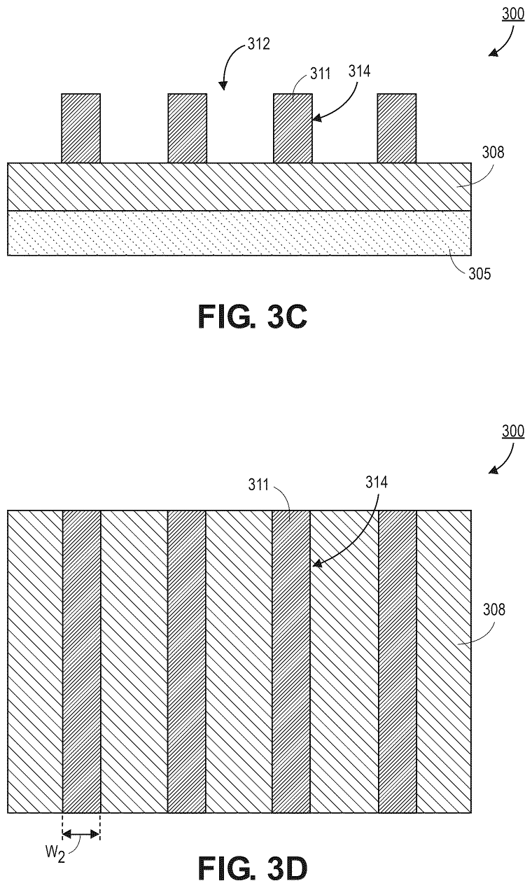

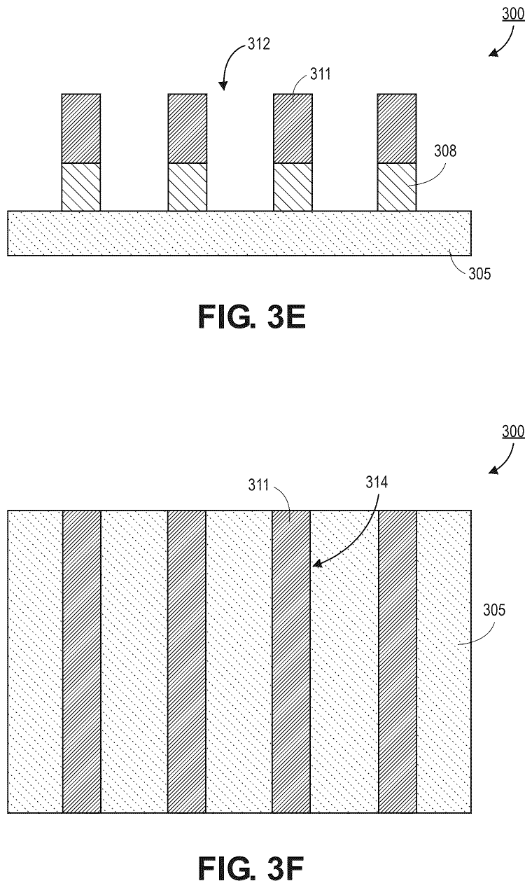

Referring now to FIG. 3A-3F, a series of cross-sectional illustrations and corresponding plan view illustrations of a device 300 during a resist developing process is shown, in accordance with an additional embodiment.

Referring now to FIG. 3A and FIG. 3B, a cross-sectional illustration (FIG. 3A) and a plan view illustration (FIG. 3B) of a portion of a device 300 is show, in accordance with an embodiment. In an embodiment, the device 300 may comprise a substrate 305. The substrate 305 may comprise a semiconductor material, such as a silicon wafer, an oxide layer, a nitride layer, a metallic layer, or the like. In an embodiment, a patterning stack (not shown) may be provided over the substrate 305. For example, the patterning stack may include one or more layers suitable for transferring a pattern formed into the resist layer 310 into the underlying substrate 305. For example, the patterning stack may comprise multiple layers, such as a silicon hardmask layer, a carbon hardmask layer, an antireflective coating, and/or the like. In some embodiments, reference to the substrate 305 herein may also refer to the patterning stack between the substrate 305 and an underlayer 308.

In an embodiment, the underlayer 308 may comprise a reflowable underlayer material. For example, the underlayer 308 may comprise a glass transition temperature that is within a particular range of a temperature used for a dry development process of the resist layer 310. In a particular embodiment, the glass transition temperature may be between approximately 150° C. and approximately 250° C. or between approximately 420 Kelvin (K) and approximately 525 K. More generally, the temperature used for the dry development process may be within ±15% of the glass transition temperature of the material of the underlayer 308 (when using the Kelvin scale), within ±10% of the glass transition temperature of the material of the underlayer 308 (when using the Kelvin scale), or within ±5% of the glass transition temperature of the underlayer 308 (when using the Kelvin scale). In some embodiments, the underlayer 308 may comprise a polymer, such as an epoxy resin, an amide, or an imide. In a particular embodiment, the underlayer 308 may comprise DMMA, MMA, PMGI, or T-butyl maleimide.

In an embodiment, the underlayer 308 may be provided between the resist layer 310 and the substrate 305. In an embodiment, the underlayer 308 may comprise a chemical structure that is also reactive to the DUV and/or EUV radiation in order to generate species that can diffuse into the resist layer 310 in order to help drive the chemical reaction within the resist layer 310 that leads to the solubility switch.

In an embodiment, the resist layer 310 may include any suitable photoresist material that is compatible with DUV and/or EUV lithography. In a particular embodiment, the resist layer 310 is a MOR material or an organometallic oxide material, such as any of those described in greater detail herein. In an embodiment, a latent image (e.g., lines 311) is formed into the resist layer with an exposure to radiation of a particular wavelength or wavelengths. For example, DUV radiation, EUV radiation, or the like may be used to initiate a solubility switch within the resist layer 310 to form the lines 311. The exposure may be made through a mask, a reticle, or the like. The resist layer 310 may also be exposed through a laser exposure, electron beam exposure, or the like. In an embodiment, the lines 311 may have a first width W₁. While the pattern of the latent image in FIG. 3B is a plurality of lines 311, other embodiments may include patterns such as pillars or the like. For example, pillars used for the latent image in the resist layer 310 may be used to generate vias, while lines 311 may be used to generate traces.

Referring now to FIG. 3C and FIG. 3D, a cross-sectional illustration (FIG. 3C) and a plan view illustration (FIG. 3D) of the portion of the device 300 after a dry develop process is shown, in accordance with an embodiment. In an embodiment, the dry develop process may include a processing gas that comprises an organic acid that includes one or more of acetic acid, formic acid, propanoic acid, lactic acid, oxalic acid, trifluoroacetic acid, difluoroacetic acid, monofluoroacetic acid, trichloroacetic acid, tribromoacetic acid, triiodoacetic acid, any isomers thereof, or the like. In another embodiment, the processing gas may comprise BCl₃. In an embodiment, the organic acid may be applied in a chamber with a pressure between approximately 0.1 Torr and 100 Torr. The duration of the dry etching process with the processing gas may comprise soaking the device 300 in the processing gas for up to approximately 0.5 minutes, up to approximately 1.0 minute, up to approximately 5.0 minutes, up to approximately 10 minutes, or up to approximately 60 minutes. Though, longer soaks in the processing gas may also be used in some embodiments.

As shown in FIG. 3D, the lines 311 may have a second width W₂ that is narrower than the first width W₁. This may be the result of volumetric changes to the lines 311 during the developing process. For example, ligand loss and film shrinking can produce a volumetric change (e.g., narrowing of the lines 311, reduction in the height of the lines 311, etc.). Since the lines 311 are securely anchored to the underlayer 308, the volumetric change may result in the generation of stress within the lines 311 when the underlayer 308 is not compliant.

Accordingly, embodiments may include a temperature of the dry develop process that is around the glass transition temperature of the material of the underlayer 308. For example, the temperature of the dry develop process may be between approximately 160° C. and approximately 210° C., between approximately 430 K and approximately 485 K, between approximately 195° C. and approximately 205° C., or between approximately 465 K and approximately 480 K. By using an elevated temperature around the glass transition temperature of the underlayer 308, stress induced in the lines 311 due to the exposure and/or developing process (e.g., due to volumetric changes in the lines 311) can be dissipated through the underlayer 308. That is, the underlayer 308 can be deformed in response to the generated stress in the lines 311. Deforming the underlayer 308 allows for the sidewall surfaces 314 to remain relatively smooth with low LER and/or LWR values.

In some embodiments, the dry develop process brings the temperature of the underlayer 308 into the range of the glass transition temperature of the underlayer 308. That is, the development process and the stress relaxation process may occur substantially at the same time. However, in other embodiments, the dry develop process may be a lower temperature process that is significantly below the glass transition temperature of the underlayer 308. In such an embodiment, the stress may persist in the lines 311. However, after the developing process, the device 300 may be heated to a temperature around the glass transition temperature of the underlayer 308. In such an embodiment, the subsequent heating may allow for the underlayer 308 to deform in order to reduce the stress within the lines 311. As such, poor LER and/or LWR values of the lines 311 may be reduced after the development process.

As shown, removal of the non-exposed portions of the resist layer 310 may result in the formation of a pattern (e.g., the lines 311). For example, openings 312 (e.g., trenches are shown in FIGS. 3C and 3D) may be formed through a thickness of the resist layer 310 in order to define the desired pattern. While trenches are shown as the openings 312 in FIG. 3C to form a line-space pattern, the openings 312 may also be holes in order to form via structures.

Referring now to FIG. 3E and FIG. 3F, a cross-sectional illustration (FIG. 3E) and a plan view illustration (FIG. 3F) of the portion of the device 300 after a pattern of the openings 312 is transferred into the underlayer 308 is shown, in accordance with an embodiment. In an embodiment, the underlayer 308 may also be patterned with a dry develop process. In some embodiments, the dry develop process used to pattern the underlayer 308 may be the same dry develop process used to form the openings 312 in the resist layer 310. Though, in other embodiments, the dry develop process for the underlayer 308 may be different than the dry develop process for the resist layer 310.

In an embodiment, the dry develop process for the underlayer 308 may be implemented at a temperature that is lower than the temperature of the dry develop process for the resist layer 310. A lower temperature may be useful to keep the underlayer 308 away from the glass transition temperature (i.e., below the glass transition temperature), in order to retain a solid foundation below the lines 311. As such, the risk of pattern collapse, pattern shifting, or other damage may be mitigated. In an embodiment, the sidewalls of the opening 312 that are formed through the underlayer 308 will also have good LER and/or LWR values due to the smooth sidewall surfaces 314 of the overlying lines 311.

After the pattern of the openings 312 is transferred into the underlayer 308, embodiments may include continuing the pattern into the substrate 305 below the underlayer 308. In some instances, the pattern of the openings 312 is first transferred into a patterning stack (not individually shown in FIG. 3E or 3F). The patterning stack may function as a hardmask for further pattern transfer, and the overlying lines 311 of the resist layer 310 and underlayer 308 may be optionally removed before transferring the pattern further into the substrate 305.

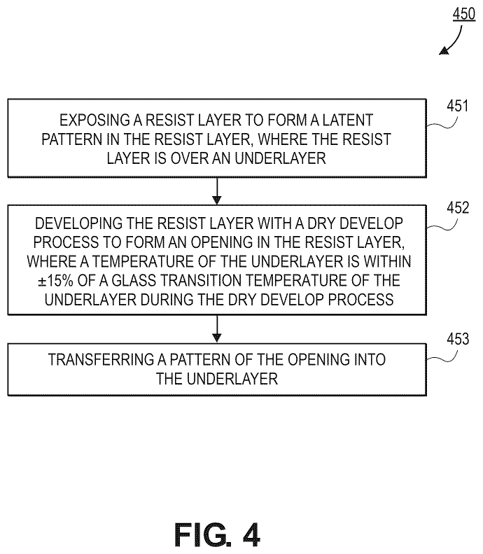

Referring now to FIG. 4, a flow diagram of a process 450 for developing a resist layer and an underlayer with a dry development process is shown, in accordance with an embodiment. In an embodiment, the process 450 may begin with operation 451, which comprises exposing a resist layer to form a latent pattern in the resist layer. In an embodiment, the resist layer is provided over an underlayer and a substrate. In an embodiment, the resist layer may comprise a MOR, an organometallic oxide material, or any other suitable resist material, such as those described in greater detail herein. In an embodiment, the underlayer may comprise a material that has a glass transition temperature that is proximate to a temperature used in a subsequent dry develop process. As such, the underlayer may deform in order to accommodate stress that is generated within the resist layer during exposure and/or development.

In an embodiment, the resist layer may be exposed with EUV radiation, DUV radiation, or the like. The exposure may be made through a mask or reticle. In an embodiment, the latent pattern may include lines of exposed resist material and/or pillars of exposed resist material. In an embodiment, the underlayer may also be reactive to the exposure radiation in order to participate in the reactions that drive a solubility switch in the resist layer that defines the latent pattern.

In an embodiment, the process 450 may continue with operation 452, which comprises developing the resist layer with a dry develop process to form an opening in the resist layer. In an embodiment, a temperature of the underlayer is brought to within ±15% of a glass transition temperature of the of the underlayer, within ±10% of the glass transition temperature of the underlayer, or within ±5% of the glass transition temperature of the underlayer during the develop process while the resist is being exposed to processing gas. For example, a processing temperature of the dry develop process may be between approximately 160° C. and approximately 210° C., between approximately 430 K and approximately 485 K, between approximately 195° C. and approximately 205° C., or between approximately 465 K and approximately 480 K.

Elevating the temperature of the underlayer during the dry develop process allows for the underlayer to deform in response to stress that is generated within the resist layer (e.g., due to volumetric changes driven by the exposure process and/or the developing process). Since the underlayer can deform at the elevated temperature, the resist layer is able to freely move to accommodate the volumetric change. As such, increases in surface roughness of the patterned resist layer are mitigated, and LER and/or LWR values of sidewalls of the opening are improved over existing solutions.

In an embodiment, the dry develop process may include a processing gas that comprises an organic acid that includes one or more of acetic acid, formic acid, propanoic acid, lactic acid, oxalic acid, trifluoroacetic acid, difluoroacetic acid, monofluoroacetic acid, trichloroacetic acid, tribromoacetic acid, triiodoacetic acid, any isomers thereof, or the like. In another embodiment, the processing gas may comprise BCl₃. In an embodiment the processing gas may comprise a hydrogen halide (e.g., HF, HCl, HBr). In an embodiment, the processing gas may be applied in a chamber with a pressure between approximately 0.1 Torr and 100 Torr. The duration of the dry etching process with the processing gas may comprise applying the processing gas for up to approximately 0.5 minutes, up to approximately 1.0 minute, up to approximately 5.0 minutes, up to approximately 10 minutes, or up to approximately 60 minutes. Though, longer processing gas durations may also be used in some embodiments.

In an embodiment, the temperature of the underlayer may also be kept below the glass transition temperature during the develop process. In such an embodiment, the resist layer is developed without allowing the underlayer to substantially deform. In such an embodiment, the resist layer may develop an internal stress. However, after the develop process, the underlayer may be heated to around the glass transition temperature in order to allow the underlayer to deform so that the stress within the resist layer is relieved and LER and/or LWR values are improved.

In an embodiment, the process 450 may continue with operation 453, which comprises transferring a pattern of the opening into the underlayer. For example, an additional etching process may be implemented in order to etch the exposed portions of the underlayer. In some embodiments, the underlayer is etched with the same processing gas used to develop the resist layer. For example, the resist layer and the underlayer may be processed with a single develop process. Though, in other embodiments the underlayer is etched with a different processing gas, and/or different processing operations are used to develop the resist layer and etch the underlayer. Due to the smooth surfaces of the sidewalls of the develop resist layer, the underlayer may also include low LER and/or LWR values. In an embodiment, the underlying substrate may then be patterned with subsequent etching processes after the pattern has been transferred into the underlayer.

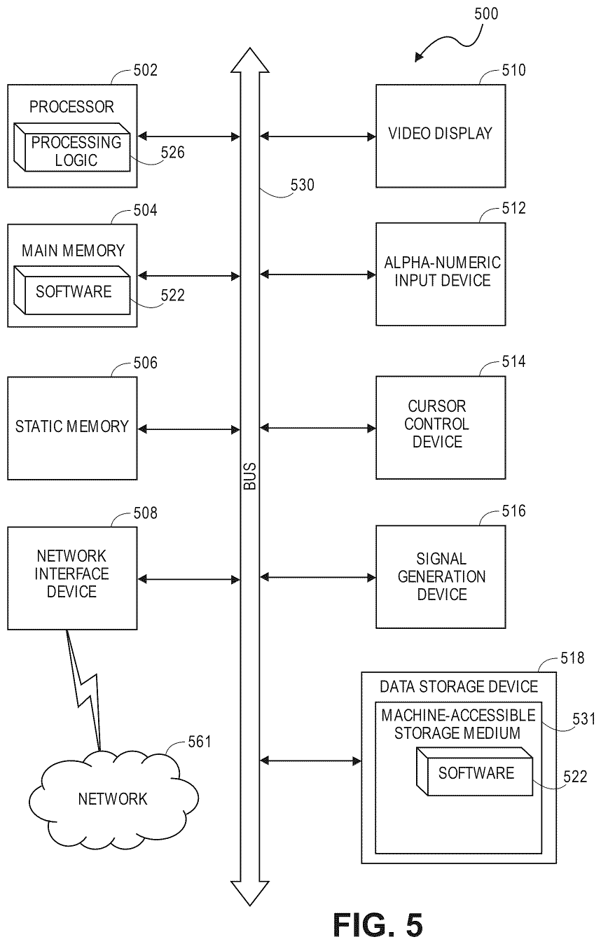

Referring now to FIG. 5, a block diagram of an exemplary computer system 500 of a processing tool is illustrated in accordance with an embodiment. In an embodiment, computer system 500 is coupled to and controls processing in the processing tool. Computer system 500 may be connected (e.g., networked) to other machines in a Local Area Network (LAN), an intranet, an extranet, or the Internet. Computer system 500 may operate in the capacity of a server or a client machine in a client-server network environment, or as a peer machine in a peer-to-peer (or distributed) network environment. Computer system 500 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 500, the term “machine” shall also be taken to include any collection of machines (e.g., computers) that individually or jointly execute a set (or multiple sets) of instructions to perform any one or more of the methodologies described herein.

Computer system 500 may include a computer program product, or software 522, having a non-transitory machine-readable medium having stored thereon instructions, which may be used to program computer system 500 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 500 includes a system processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

System processor 502 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 502 may also be one or more special-purpose processing devices such as an application specific integrated circuit (ASIC), a field programmable gate array (FPGA), a digital signal system processor (DSP), network system processor, or the like. System processor 502 is configured to execute the processing logic 526 for performing the operations described herein.

The computer system 500 may further include a system network interface device 508 for communicating with other devices or machines. The computer system 500 may also include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium 531 (or more specifically a computer-readable storage medium) on which is stored one or more sets of instructions (e.g., software 522) embodying any one or more of the methodologies or functions described herein. The software 522 may also reside, completely or at least partially, within the main memory 504 and/or within the system processor 502 during execution thereof by the computer system 500, the main memory 504 and the system processor 502 also constituting machine-readable storage media. The software 522 may further be transmitted or received over a network 561 via the system network interface device 508. In an embodiment, the network interface device 508 may operate using RF coupling, optical coupling, acoustic coupling, or inductive coupling.

While the machine-accessible storage medium 531 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method of developing a resist layer on a substrate that has been selectively exposed with a lithography process, wherein an underlayer is below the resist layer, the method comprising:
developing the resist layer with a dry develop process to form an opening in the resist layer, wherein a temperature of the dry develop process using the Kelvin scale is within ±15% of a glass transition temperature of the underlayer.

2. The method of claim 1, wherein the resist layer is a metal oxide resist material.

3. The method of claim 1, wherein the temperature is between 430 K and 485 K.

4. The method of claim 3, wherein the temperature is between 465 K and 480 K.

5. The method of claim 1, wherein the dry develop process comprises a chemistry comprising an organic acid.

6. The method of claim 1, wherein the dry develop process comprises a chemistry comprising BCl₃ or a hydrogen halide.

7. The method of claim 1, wherein the underlayer comprises an epoxy resin, an amide, or an imide.

8. The method of claim 7, wherein the underlayer comprises N, N-dimethylacrylamide (DMMA), methyl methacrylate (MMA), polydimethylglutarimide (PMGI), or t-butyl maleimide.

9. The method of claim 1, wherein the opening is a trench through the resist layer.

10. The method of claim 1, wherein the lithography process comprises an extreme ultraviolet (EUV) exposure of the resist layer.

11. The method of claim 1, further comprising:
transferring a pattern of the opening into the underlayer.

12. A method of developing a resist layer on a substrate that has been selectively exposed with a lithography process, wherein an underlayer is below the resist layer, the method comprising:
developing the resist layer with a dry develop process to form an opening in the resist layer, wherein the underlayer is deformable to dissipate stress that is generated in the resist layer during the dry develop process.

13. The method of claim 12, wherein the underlayer is deformable when at a temperature using the Kelvin scale that is within ±15% of a glass transition temperature of the underlayer.

14. The method of claim 12, wherein the dry develop process comprises an organic acid.

15. The method of claim 14, wherein the organic acid is acetic acid.

16. The method of claim 12, wherein the underlayer comprises N, N-dimethylacrylamide (DMMA), methyl methacrylate (MMA), polydimethylglutarimide (PMGI), or t-butyl maleimide.

17. The method of claim 12, wherein the resist layer is a metal oxide resist material.

18. A method, comprising:
developing a resist layer that is provided over an underlayer with a dry develop process to form an opening through the resist layer, wherein a temperature of the dry develop process using the Kelvin scale is within ±15% of a glass transition temperature of the underlayer.

19. The method of claim 18, wherein the underlayer comprises an epoxy resin, an amide, or an imide.

20. The method of claim 19, wherein the resist layer is a metal oxide resist material, and wherein the underlayer comprises N, N-dimethylacrylamide (DMMA), methyl methacrylate (MMA), polydimethylglutarimide (PMGI), or t-butyl maleimide.
